(19) United States
(12) Patent Application Publication
(10) Pub. No.: US 2025/0174555 A1
(43) Pub. Date: May 29, 2025

(54) SEMICONDUCTOR CHIP, SEMICONDUCTOR PACKAGE, AND SEMICONDUCTOR CHIP MANUFACTURING METHOD

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/767,390

(22) Filed: Jul. 9, 2024

(30) Foreign Application Priority Data
Nov. 23, 2023 (KR) 10-2023-0164519

(51) Int. Cl. H01L 23/528; H01L 21/304; H01L 21/308; H01L 23/00

(52) U.S. Cl. CPC H01L 23/5283; H01L 21/3043; H01L 21/308; H01L 23/528; H01L 24/08; H01L 24/32; H01L 24/83; H01L 24/97; H01L 2224/08145; H01L 2224/32145; H01L 2224/83895; H01L 2224/83896; H01L 2224/97; H01L 2924/13067; H01L 2924/13091

(57) ABSTRACT

A semiconductor chip includes a semiconductor substrate, a bonding layer above an upper surface of the semiconductor substrate, the bonding layer including a bonding pad and a bonding insulating layer surrounding at least a portion of a side surface of the bonding pad, and a circuit layer between the semiconductor substrate and the bonding layer, the circuit layer including a circuit insulating layer and an electric line in the circuit insulating layer, where a horizontal width of the circuit layer is less than a horizontal width of the semiconductor substrate, and a sidewall of the semiconductor substrate is spaced apart from a sidewall of the circuit layer in a horizontal direction.

### CROSS-REFERENCE TO RELATED APPLICATION

This application is based on and claims priority under 35 U.S.C. § 119 to Korean Patent Application No. 10-2023-0164519, filed on Nov. 23, 2023, in the Korean Intellectual Property Office, the disclosure of which is incorporated by reference herein in its entirety.

### BACKGROUND

The present disclosure relates to a semiconductor chip, a semiconductor package, and a semiconductor chip manufacturing method.

As semiconductor devices are highly integrated and have high capacities, there is a need to develop system-in-package (SiP) technology that embeds a plurality of semiconductor chips performing different functions in a single package. In order to form fine lines that connect semiconductor chips to each other in a package, technology for bonding the semiconductor chips to each other via bonding pads has been used.

### SUMMARY

Example embodiments provide a semiconductor chip that may have improved electrical characteristics and/or reliability of the front surface of the semiconductor chip, a semiconductor package that may have improved electrical characteristics and/or reliability between a plurality of semiconductor chips, and a semiconductor chip manufacturing method that may improve electrical characteristics and/or reliability.

Additional aspects will be set forth in part in the description which follows and, in part, will be apparent from the description, or may be learned by practice of the presented embodiments.

According to an aspect of an example embodiment, a semiconductor chip may include a semiconductor substrate, a bonding layer above an upper surface of the semiconductor substrate, the bonding layer including a bonding pad and a bonding insulating layer surrounding at least a portion of a side surface of the bonding pad, and a circuit layer between the semiconductor substrate and the bonding layer, the circuit layer including a circuit insulating layer and an electric line in the circuit insulating layer, where a horizontal width of the circuit layer is less than a horizontal width of the semiconductor substrate, and a sidewall of the semiconductor substrate is spaced apart from a sidewall of the circuit layer in a horizontal direction.

According to an aspect of an example embodiment, a semiconductor package may include a semiconductor structure, and a semiconductor chip on the semiconductor structure, where the semiconductor structure may include a first semiconductor substrate, a first bonding layer on an upper surface of the first semiconductor substrate, the first bonding layer including a first bonding pad and a first bonding insulating layer surrounding at least a portion of a side surface of the first bonding pad, and a first circuit layer on a lower surface of the first semiconductor substrate, the first circuit layer including a first circuit insulating layer and a first electric line in the first circuit insulating layer, where the semiconductor chip may include a second semiconductor substrate, a second bonding layer below the second semiconductor substrate, the second bonding layer including a second bonding pad and a second bonding insulating layer surrounding at least a portion of a side surface of the second bonding pad, and a second circuit layer between the second semiconductor substrate and the second bonding layer, the second circuit layer including a second circuit insulating layer and a second electric line in the second circuit insulating layer, and where a horizontal width of the second circuit layer is less than a horizontal width of the second semiconductor substrate.

According to an aspect of an example embodiment, a semiconductor chip manufacturing method may include preparing a semiconductor wafer including a plurality of chip regions and a plurality of scribe lane regions between the plurality of chip regions, where the semiconductor wafer includes a semiconductor substrate, a bonding layer above the semiconductor substrate, and a circuit layer between the semiconductor substrate and the bonding layer, and where each of the plurality of scribe lane regions includes an inspection region and trench regions on both sides of the inspection region, forming a first mask layer on a front surface of the semiconductor wafer, forming a first mask pattern by performing a first laser grooving process on the first mask layer in the trench regions, removing a portion of a bonding insulating layer of the bonding layer and removing a portion of a circuit insulating layer of the circuit layer by performing a first plasma process in the trench regions using the first mask pattern as an etch mask, removing the first mask pattern, forming a second mask layer filling a space corresponding to the removed portion of the bonding insulating layer and the removed portion of the circuit insulating layer, removing at least a portion the second mask layer, the bonding layer, and the circuit layer from the inspection region by performing a second laser grooving process, removing the semiconductor substrate from the inspection region by performing a second plasma process, and removing the second mask layer from at least one region other than the inspection region.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a flowchart illustrating bonding between a plurality of semiconductor chips of a semiconductor package according to one or more example embodiments;

FIG. 2 is a cross-sectional view illustrating bonding between a plurality of semiconductor chips of a semiconductor package according to one or more example embodiments;

FIG. 3A is a plan view illustrating scribe lane regions in a semiconductor wafer according to one or more example embodiments;

FIG. 3B is an enlarged view illustrating region ‘A’ of FIG. 3A according to one or more example embodiments;

FIG. 4 is a flowchart illustrating a semiconductor chip manufacturing method according to one or more example embodiments;

FIGS. 5A to 5G are cross-sectional views sequentially illustrating a semiconductor chip manufacturing method according to one or more example embodiments;

FIG. 6 is a cross-sectional view illustrating a semiconductor chip manufactured by a semiconductor chip manufacturing method according to one or more example embodiments;

FIG. 7 is a diagram illustrating a die-to-wafer bonding process according to one or more example embodiments; and

FIG. 8 is a cross-sectional view illustrating a semiconductor chip and a semiconductor package according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

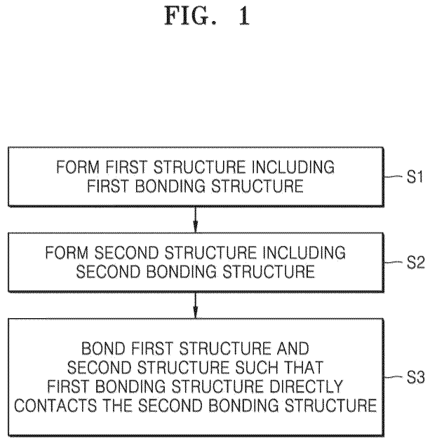

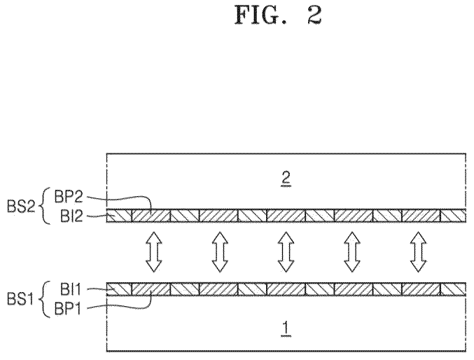

FIG. 1 is a flowchart illustrating bonding between a plurality of semiconductor chips of a semiconductor package according to one or more example embodiments. FIG. 2 is a cross-sectional view illustrating bonding between the plurality of semiconductor chips of the semiconductor package according to one or more example embodiments.

Referring to FIGS. 1 and 2, a first structure 1 including a first bonding structure BS1 may be formed in operation S1, a second structure 2 including a second bonding structure BS2 may be formed in operation S2, and the first structure 1 and the second structure 2 may be bonded to each other such that the first bonding structure BS1 directly contacts the second bonding structure BS2 in operation S3.

It should be understood that in this specification, terms such as “first” and “second” may be used to distinguish components from each other and are not intended to represent the order of the components.

The first bonding structure BS1 may include a first bonding pad BP1 and a first bonding insulating layer BI1 surrounding at least a portion of the side surface of the first bonding pad BP1. The second bonding structure BS2 may include a second bonding pad BP2 and a second bonding insulating layer BI2 surrounding at least a portion of the side surface of the second bonding pad BP2. The first bonding pad BP1 and the second bonding pad BP2 may be brought into contact with and coupled to each other by copper-to-copper bonding. The first bonding insulating layer BI1 and the second bonding insulating layer BI2 may be brought into contact with and coupled to each other by dielectric-to-dielectric bonding. The first bonding structure BS1 and the second bonding structure BS2 may be electrically connected to redistribution layers or through silicon vias (TSVs) arranged in the first structure 1 and the second structure 2, respectively.

In one or more embodiments, the first structure 1 and the second structure 2 may be coupled to each other by die-to-die bonding or die-to-wafer bonding. For example, when each of the first structure 1 and the second structure 2 includes a semiconductor die, the first structure 1 and the second structure 2 may be coupled to each other by the die-to-die bonding.

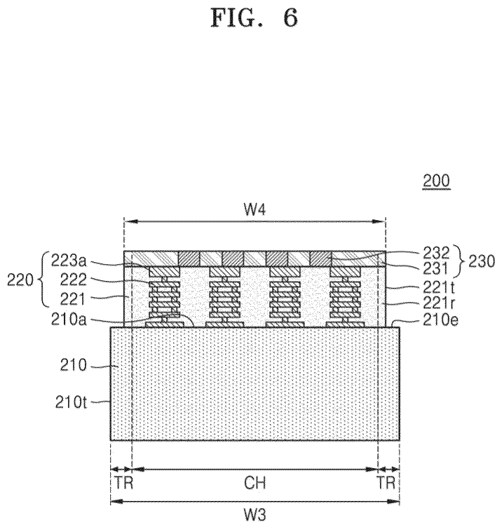

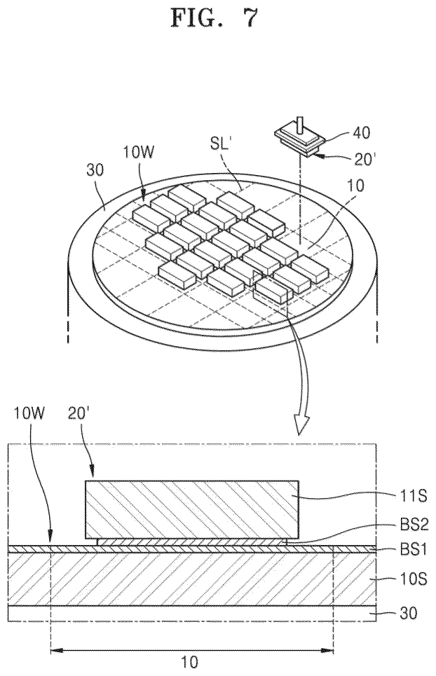

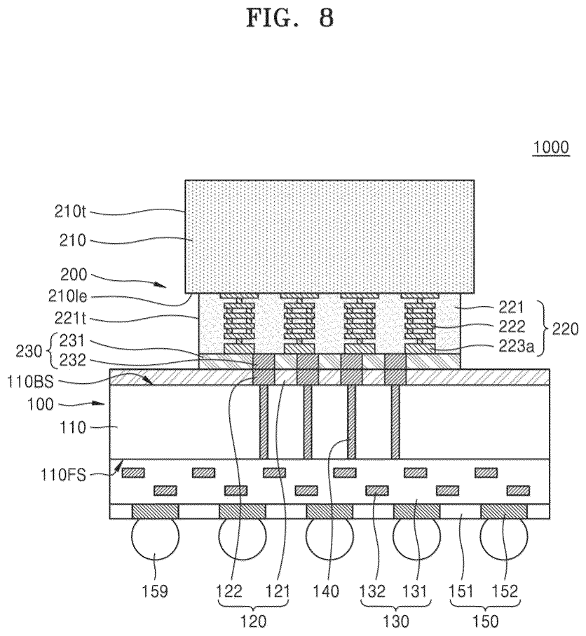

For example, if the first structure 1 includes one of a plurality of semiconductor structures (e.g., 10 in FIG. 7) divided by scribe lanes on a semiconductor wafer and the second structure 2 includes a semiconductor die, the first structure 1 and the second structure 2 may be coupled to each other by the die-to-wafer bonding. Here, the semiconductor die may correspond to a semiconductor chip 200 in FIGS. 6 and 8 or a semiconductor chip 20′ in FIG. 7.

For example, when the first structure 1 and the second structure 2 include one of the plurality of semiconductor structures (e.g., 10 in FIG. 7) divided by the scribe lanes on a first semiconductor wafer and a second semiconductor wafers, respectively, the first structure 1 and the second structure 2 may be coupled to each other by the wafer-to-wafer bonding.

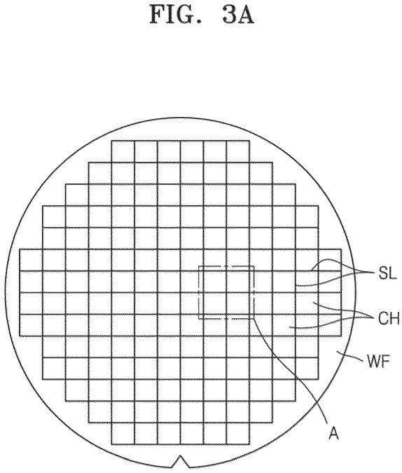

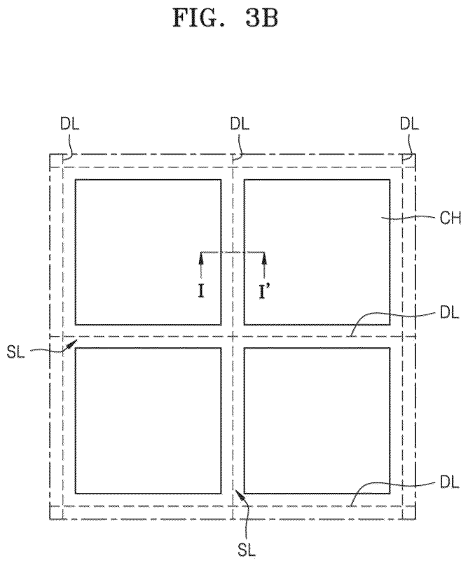

FIG. 3A is a plan view illustrating a scribe lane region SL on a semiconductor wafer WF according to one or more example embodiments. FIG. 3B is an enlarged view illustrating region ‘A’ of FIG. 3A according to one or more example embodiments.

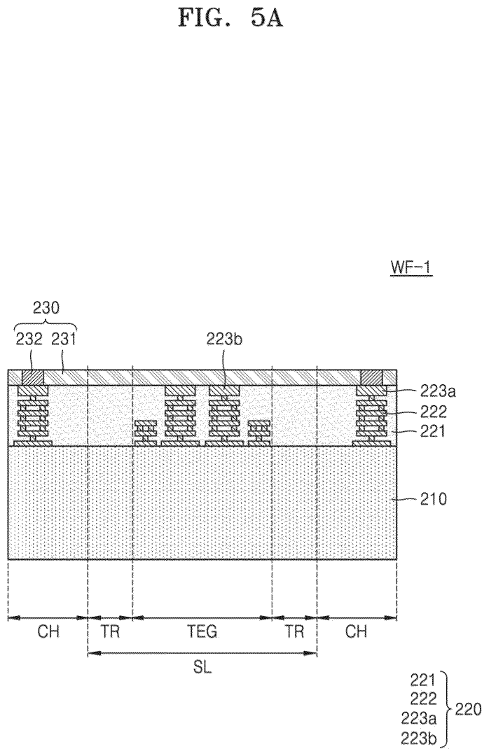

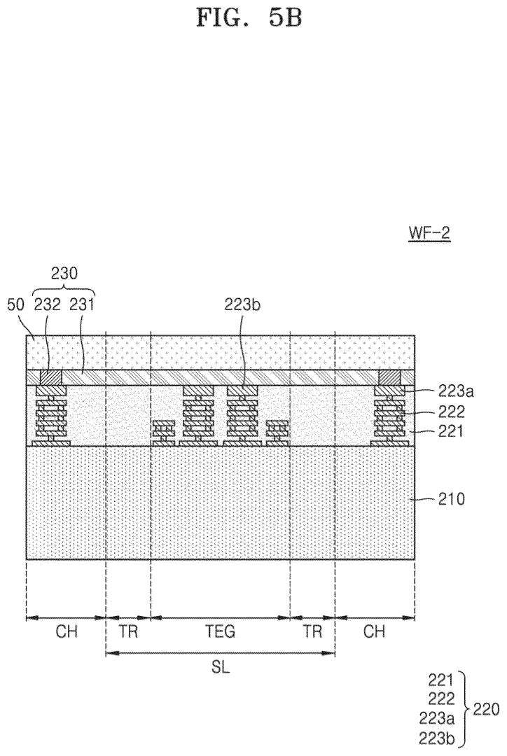

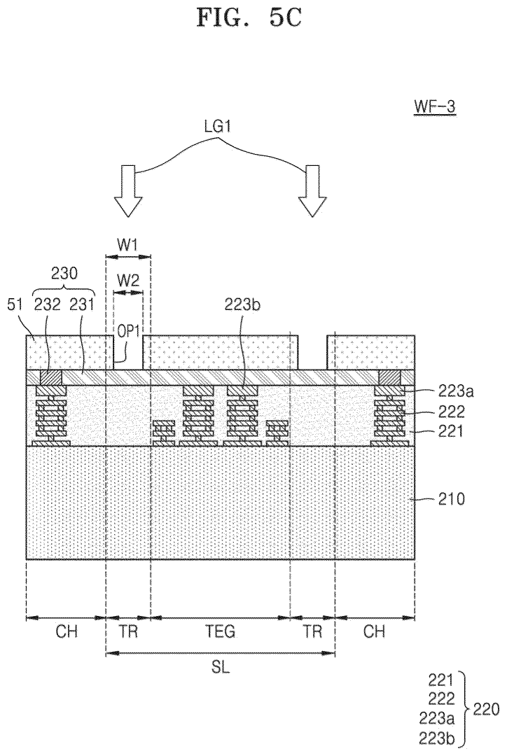

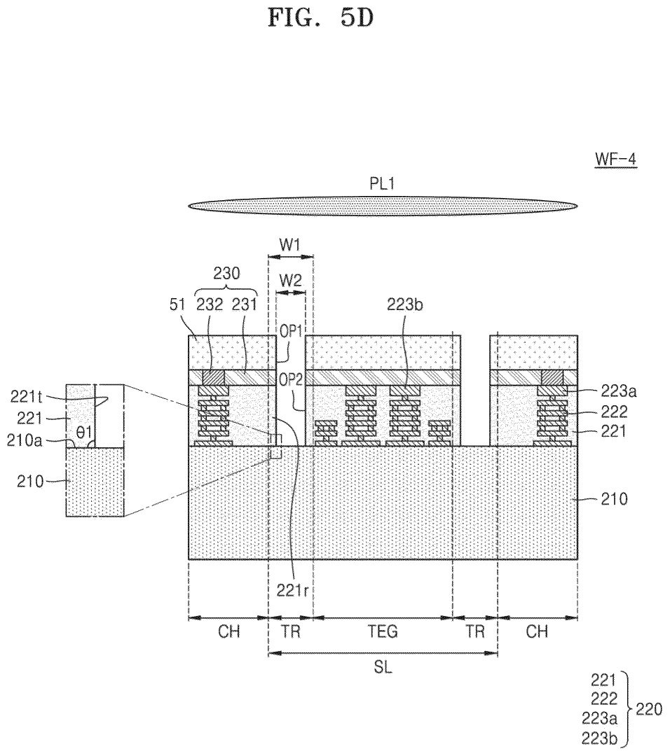

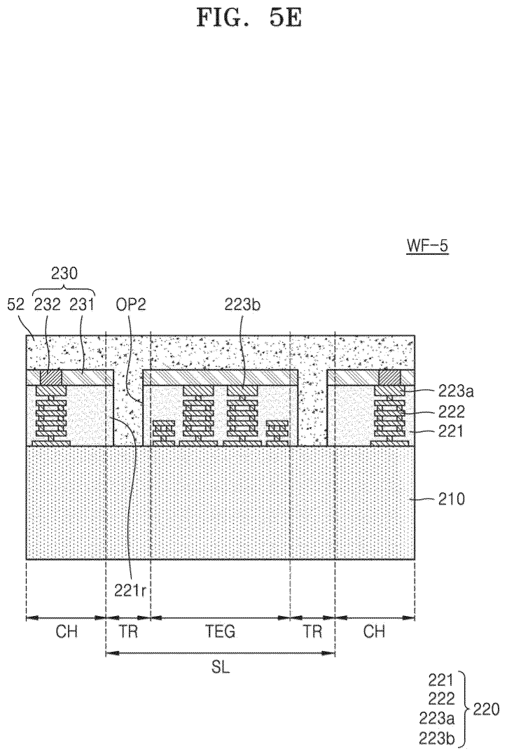

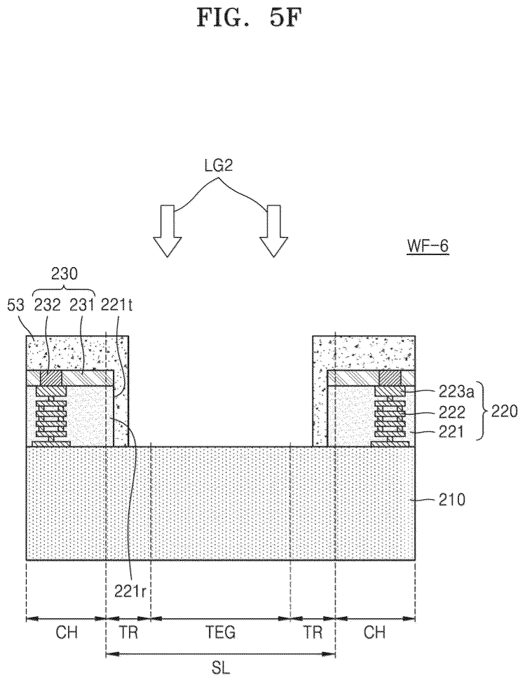

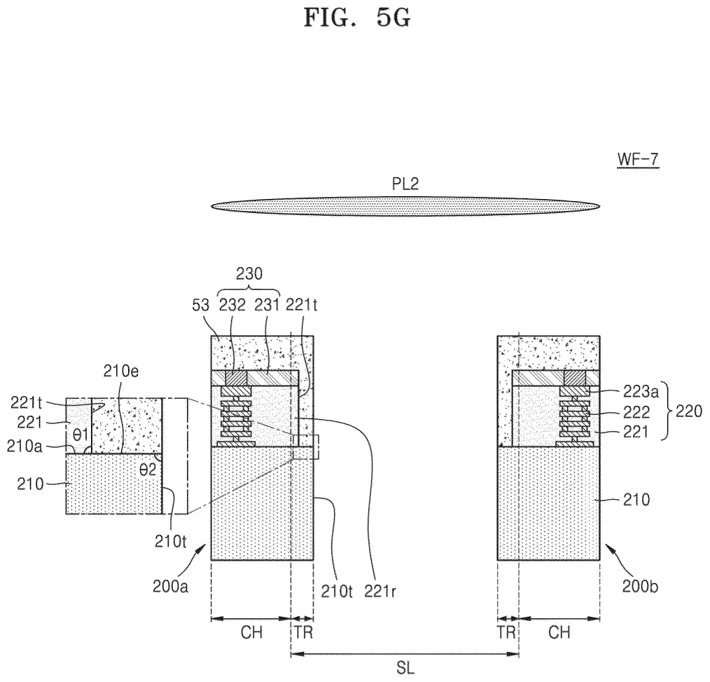

Referring to FIGS. 3A and 3B, the semiconductor wafer WF may be prepared, which includes a plurality of chip regions CH and a plurality of scribe lane regions SL between the plurality of chip regions CH. The semiconductor wafer WF may be in a state before dicing. Each of the plurality of scribe lane region SL may include a region through which a dicing line DL passes. Here, the dicing line DL may be a virtual line. The dicing process may include cutting the semiconductor wafer WF along the dicing lines DL. The semiconductor wafer WF may include a first semiconductor substrate 210, a first circuit layer 220, and a first bonding layer 230 shown in FIGS. 5A to 5G, which are described below.

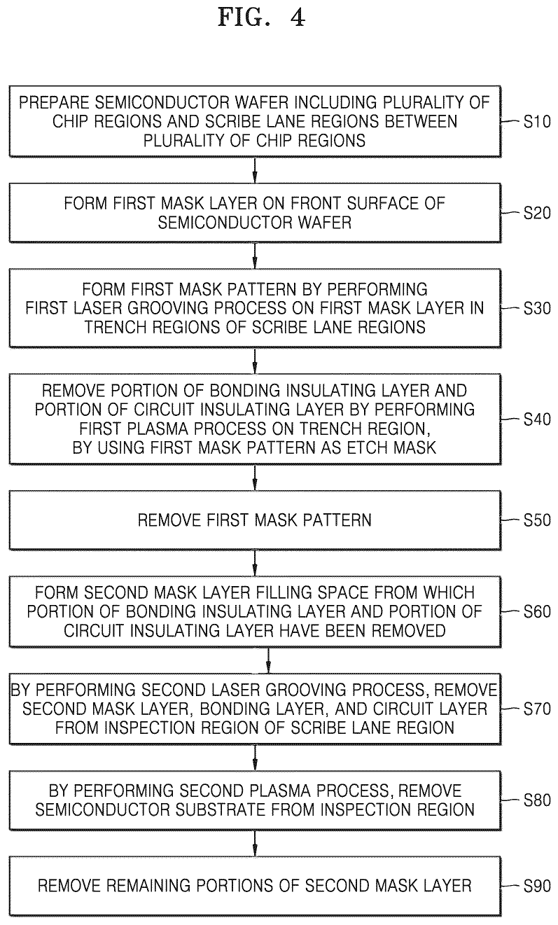

FIG. 4 is a flowchart illustrating a semiconductor chip manufacturing method according to one or more example embodiments. FIGS. 5A to 5G are cross-sectional views sequentially illustrating the semiconductor chip manufacturing method according to one or more example embodiments. FIGS. 5A to 5G show the process of dicing a semiconductor wafer and forming a plurality of semiconductor chips 200a and 200b as finally depicted in FIG. 5G on the cross-section of the semiconductor wafer taken along line I-I′ of FIG. 3B.

Referring to FIGS. 4 and 5A, the semiconductor chip manufacturing method according to one or more embodiments may include an operation S10 of preparing a semiconductor wafer WF-1 in a first state. In the first state, the wafer WF-1 may include a plurality of chip regions CH and a plurality of scribe lane regions SL between the plurality of chip regions CH. The semiconductor wafer WF-1 in the first state may have a structure in which a first semiconductor substrate 210, a first circuit layer 220, and a first bonding layer 230 are stacked on each other. The first circuit layer 220 may be located between the first semiconductor substrate 210 and the first bonding layer 230.

The first semiconductor substrate 210 may include semiconductor elements, such as silicon and germanium, or compound semiconductors, such as silicon carbide (SiC), gallium arsenide (GaAs), indium arsenide (InAs), and indium phosphide (InP), and may optionally include a TSV.

A device layer may be formed on the first semiconductor substrate 210, and the device layer may include transistors constituting an integrated circuit. The transistors constituting the integrated circuit may include, but not limited to, a metal oxide semiconductor (MOS) field effect transistor (FET) (MOSFET) having a planar shape, a fin FET (FinFET) having an active region of a fin structure, a multi bridge channel FET (MBCFET™) including a plurality of channels stacked vertically on an active region, a gate-all-around transistor (GAAFET), a vertical FET (VFET), etc.

The integrated circuit may include volatile memory devices, such as a dynamic random access memory (RAM) (DRAM) and a static RAM (SRAM), and non-volatile memory devices, such as a phase-change RAM (PRAM), a magnetic RAM (MRAM), and a resistive RAM (ReRAM).

The first circuit layer 220 may be disposed on the first semiconductor substrate 210. The first circuit layer 220 may include a first circuit insulating layer 221, a first electric line 222, a first connection pad 223a, and a second connection pad 223b. The first electric line 222 and the first and second connection pads 223a and 223b may be arranged within the first circuit insulating layer 221.

The first electric line 222 may be electrically connected to the integrated circuit of the device layer. The first connection pad 223a may be located in each of the plurality of chip regions CH and the second connection pad 223b may be located in each of the scribe lane regions SL. Each of the first and second connection pads 223a and 223b may be electrically connected to the corresponding first electric line 222.

Each of the scribe lane regions SL may include an inspection region TEG and trench regions TR on both sides of the inspection region TEG. That is, a scribe lane region SL may include an inspection region TEG, a first trench region TR on a first side of the inspection region TEG, and a second trench region TR on a second side of the inspection region TEG in the cross-sectional view. The inspection region TEG may include a region in which the first electric line 222 and the second connection pad 223b are arranged.

In the inspection region TEG, an inspection circuit that may test in advance whether or not individual semiconductor chips of the semiconductor wafer WF-1 in the first state are operating may be provided in the first semiconductor substrate 210 or the first circuit insulating layer 221.

In the inspection region TEG, an align-key for aligning photo masks during a photolithography process may be provided in the first semiconductor substrate 210 or the first circuit insulating layer 221. The inspection circuit or align-key may include the first electric line 222 and the second connection pad 223b, which are arranged in the inspection region TEG.

The trench region TR may be located between the chip region CH and the inspection region TEG. The trench region TR may include a region in which the first electric line 222, the first connection pad 223a, and the second connection pad 223b are not arranged. In other words, the first electric line 222, the first connection pad 223a, and the second connection pad 223b may be spaced apart from the trench region TR in the horizontal direction. The first circuit insulating layer 221 may be provided in the trench region TR. The first circuit insulating layer 221 may be provided as a single layer or as multiple layers.

For example, the first circuit insulating layer 221 may include silicon oxide (SiO), silicon nitride (SiN), silicon oxynitride (SiON), silicon oxycarbide (SiOC), silicon carbonitride (SiCN), or a combination thereof.

Each of the first electric line 222, the first connection pad 223a, and the second connection pad 223b may include aluminum (Al), gold (Au), cobalt (Co), copper (Cu), nickel (Ni), lead (Pb), tantalum (Ta), tellurium (Te), titanium (Ti), tungsten (W), or a combination thereof.

A barrier film containing titanium (Ti), titanium nitride (TiN), tantalum (Ta), or tantalum nitride (TaN) may be provided between the first electric line 222 and the first circuit insulating layer 221.

The first bonding layer 230 may be disposed on the first circuit layer 220. The first bonding layer 230 may include a first bonding pad 232 and a first bonding insulating layer 231 surrounding at least a portion of the side surface of the first bonding pad 232. The first bonding layer 230 may correspond to the first bonding structure BS1 or the second bonding structure BS2 in FIG. 2. The first bonding insulating layer 231 may correspond to the first bonding insulating layer BI1 and/or the second bonding insulating layer BI2 in FIG. 2. The first bonding pad 232 may correspond to the first bonding pad BP1 and/or the second bonding pad BP2 in FIG. 2.

A plurality of first bonding pads 232 may be provided. The plurality of first bonding pads 232 may be respectively arranged in the plurality of chip regions CH. The first bonding pad 232 may be connected to the first connection pad 223a. The first bonding pad 232 may be electrically connected to the first electric line 222 via the first connection pad 223a. The first bonding pad 232 may be electrically connected to the integrated circuit of the first semiconductor substrate 210 via the first connection pad 223a and the first electric line 222.

The horizontal width of the first bonding pad 232 may be less than the horizontal width of the first connection pad 223a and the horizontal width of the second connection pad 223b. The horizontal width of the first connection pad 223a and the horizontal width of the second connection pad 223b may each be greater than the horizontal width of the first bonding pad 232.

For example, the first bonding insulating layer 231 may include silicon oxide, silicon nitride, silicon oxynitride, silicon carbide, silicon oxycarbide, silicon carbonitride, or a combination thereof. The first bonding pad 232 may include any one of copper (Cu), nickel (Ni), gold (Au), and silver (Ag), or an alloy thereof.

Next, referring to FIGS. 4 and 5B, the semiconductor wafer WF-1 in the first state may be subjected to an operation S20 of forming a first mask layer 50 on the entire surface of the semiconductor wafer WF-1, and thus, a semiconductor wafer WF-2 in a second state may be formed. The first mask layer 50 may include a photosensitive material, such as a photo resist, or a non-photosensitive material, such as a protective layer coating (PLC). For example, the PLC may include water-soluble polymers, such as acrylic polymers, ether polymers, fluorocarbon polymers, polystyrene polymers, and polyvinyl chloride polymers.

Referring to FIGS. 4 and 5C, the semiconductor wafer WF-2 in the second state may be subjected to an operation S30 of forming a first mask pattern 51 by performing a first laser grooving process LG1 on the first mask layer 50 in the trench region TR of the scribe lane region SL, and thus, a semiconductor wafer WF-3 in a third state may be formed.

The first laser grooving process LG1 may include emitting a laser beam downward onto the upper surface of the first mask layer 50 (FIG. 5B). A portion of the first mask layer 50 may be removed by the first laser grooving process LG1. A first opening OP1 may be formed by partially removing the first mask layer 50, and thus, the first mask pattern 51 may be formed from the first mask layer 50.

The horizontal width of the trench region TR may be a first width W1. The horizontal width of the first opening OP1 may be a second width W2. The second width W2 of the first opening OP1 may be the width of the removed portion of the first mask layer 50. The first width W1 of the trench region TR may be greater than the second width W2 of the first opening OP1. That is, the second width W2 may be less than the first width W1.

Referring to FIGS. 4 and 5D, the semiconductor wafer WF-3 in the third state may be subjected to an operation S40 of removing a portion of the first bonding insulating layer 231 and a portion of the first circuit insulating layer 221 by performing a first plasma process PL1 in the trench region TR using the first mask pattern 51 as an etch mask, and thus, a semiconductor wafer WF-4 in a fourth state may be formed.

The first plasma process PL1 may include a plasma process using O₂ plasma gas. Also, the first plasma process PL1 may include a plasma process using CₓF_{y} or CHₓF_{y} plasma gas. x and y of CₓF_{y} and CHₓF_{y} may represent natural numbers. For example, CₓF_{y} may include C₄F₅ or C₄F₆, and CHₓF_{y} may include CH₂F₂.

The portion of the first bonding insulating layer 231 and the portion of the first circuit insulating layer 221 may be removed by the first plasma process PL1, thereby forming a second opening OP2. The first opening OP1 may vertically overlap the second opening OP2. The horizontal width of the second opening OP2 may be substantially the same as the horizontal width of the first opening OP1. That is, the horizontal width of the second opening OP2 may be the second width W2.

The second width W2 is less than the first width W1, and thus, a portion of the first circuit insulating layer 221 and a portion of the first bonding insulating layer 231 may remain in the trench region TR even after the first plasma process PL1 has been performed. A layer defined by combining the remaining portion of the first circuit insulating layer 221 and the remaining portion of the first bonding insulating layer 231 may be referred to as a remaining insulating layer 221r.

A sidewall 221t of the remaining insulating layer 221r may be exposed through the second opening OP2. The sidewall 221t of the remaining insulating layer 221r may also be referred to as the sidewall of the first circuit insulating layer 221 or the sidewall of the first bonding insulating layer 231. The sidewall 221t of the remaining insulating layer 221r may also be referred to as the sidewall of the first circuit layer 220 or the sidewall of the first bonding layer 230 or may also be referred to as the sidewall of the first circuit insulating layer 221 or the sidewall of the first bonding insulating layer 231.

The sidewall 221t of the remaining insulating layer 221r and an upper surface 210a of the first semiconductor substrate 210 may form a first angle θ1. For example, the first angle θ1 may be about 90 degrees. In another example, the first angle θ1 may be at least about 60 degrees but less than about 90 degrees. The range of the first angle θ1 may be due to the characteristics of the first plasma process PL1.

A portion of the upper surface 210a of the first semiconductor substrate 210 may be exposed via the first opening OP1 and the second opening OP2. That is, the first plasma process PL1 may not remove the first semiconductor substrate 210.

Referring to FIGS. 4 and 5E, the semiconductor wafer WF-4 in the fourth state may be subjected to an operation S50 of removing the first mask pattern 51 and an operation S60 of forming a second mask layer 52 that fills a space from which the portion of the first bonding insulating layer 231 and the portion of the first circuit insulating layer 221 have been removed, and thus, a semiconductor wafer WF-5 in a fifth state may be formed.

The second mask layer 52 may fill the second opening OP2 in FIG. 5D and cover the upper surface of the first bonding insulating layer 231. The second mask layer 52 may include a photosensitive material, such as a photo resist, or a non-photosensitive material, such as a PLC.

Referring to FIGS. 4 and 5F, the semiconductor wafer WF-5 in the fifth state may be subjected to an operation S70 of removing the second mask layer 52, the first bonding layer 230, and the first circuit layer 220 in the inspection region TEG of the scribe lane region SL by performing a second laser grooving process LG2, and thus, a semiconductor wafer WF-6 in a sixth state may be formed. The second laser grooving process LG2 may include emitting a laser beam downward onto the upper surface of the semiconductor wafer WF-5 in the fifth state.

As the first bonding layer 230 and the first circuit layer 220 are removed from the inspection region TEG, the first bonding layer 230 and the first circuit layer 220 may also be removed from a portion of the trench region TR adjacent to the inspection region TEG (i.e., a portion of the first bonding layer 230 and the first circuit layer 220 in the trench region TR that is closer to the inspection region TEG than the chip region CH). On the other hand, the remaining insulating layer 221r located in another portion of the trench region TR adjacent to the chip region CH (i.e., in a portion of the trench region TR that is closer to the chip region CH than the inspection region TEG) may not be removed.

While performing the second laser grooving process LG2, the second mask layer 52 overlapping the inspection region TEG may be completely removed. On the other hand, while performing the second laser grooving process LG2, the second mask layer 52 overlapping the trench region TR may be partially removed. In other words, the second laser grooving process LG2 may be performed in a state in which the second mask layer 52 covers the sidewall 221t of the remaining insulating layer 221r in a portion of the trench region TR adjacent to the chip region CH (i.e., a portion of the trench region TR that is closer to the chip region CH than the inspection region TEG). Even after the second laser grooving process LG2 has been performed, the second mask layer 52 may cover the sidewall 221t of the remaining insulating layer 221r. Accordingly, the sidewall 221t of the remaining insulating layer 221r may not be exposed to the outside.

During the second laser grooving process LG2, a first portion of the second mask layer 52 adjacent to the inspection region TEG (i.e., a portion of the second mask layer 52 in the trench region TR that is closer to the inspection region TEG than the chip region CH) may be removed from the trench region TR, and a second portion of the second mask layer 52 adjacent to the chip region CH may remain in the trench region TR (i.e., a portion of the second mask layer 52 that is closer to the chip region CH than the inspection region TEG).

While performing the second laser grooving process LG2, a second mask pattern 53 may be formed from the second mask layer 52. The second mask pattern 53 may include the remaining portion of the second mask layer 52 that remains after performing the second laser grooving process LG2 (i.e., the remaining portion that is not removed after performing the second laser grooving process LG2).

Referring to FIGS. 4 and 5G, the semiconductor wafer WF-6 in the sixth state may be subjected to an operation S80 of removing the first semiconductor substrate 210 from the inspection region TEG by performing a second plasma process PL2, and thus, a semiconductor wafer WF-7 in a seventh state may be formed.

While performing the second plasma process PL2, the first semiconductor substrate 210 may be completely removed from the inspection region TEG. As a result, the first semiconductor substrate 210 may be separated into a plurality of segments, and a sidewall 210t of each of first semiconductor substrates 210 may be exposed. The first semiconductor substrate 210 is divided into a plurality of segments, and thus, the semiconductor wafer WF-7 in the seventh state may include a plurality of semiconductor chips 200a and 200b. Each of the plurality of semiconductor chips 200a and 200b may include the first semiconductor substrate 210, the first circuit layer 220, and the first bonding layer 230. Each of the plurality of semiconductor chips 200a and 200b may include the remaining insulating layer 221r in the trench region TR.

A portion of the first semiconductor substrate 210 located in the trench region TR may not be removed. Accordingly, the first semiconductor substrate 210 may have an upper edge surface 210e (e.g., an edge portion of the upper surface of the first semiconductor substrate 210). The upper edge surface 210e of the first semiconductor substrate 210 may be defined as a portion of the upper surface 210a of the first semiconductor substrate 210, which is located in the trench region TR. The upper edge surface 210e may be defined as a portion located at the edge of the upper surface 210a of the first semiconductor substrate 210. The upper edge surface 210e may be spaced apart from the first circuit layer 220 and the first bonding layer 230 in the horizontal direction. The upper edge surface 210e may not be covered by the first circuit layer 220 and the first bonding layer 230, but may be covered by the second mask pattern 53 in the seventh state WF-7.

The angle formed between the upper edge surface 210e of the first semiconductor substrate 210 and the sidewall 210t of the first semiconductor substrate 210 may be a second angle θ2. For example, the second angle θ2 may be about 90 degrees. In another example, the second angle θ2 may be greater than about 90 degrees but less than about 120 degrees. The range the second angle θ2 may be due to the characteristics of the second plasma process PL2.

For example, the second plasma process PL2 may alternately and repeatedly use SF₆ plasma gas and C₄F₈ plasma gas. Also, the second plasma process PL2 may include a plasma process using O₂ plasma gas. Also, the second plasma process PL2 may include a plasma process using CₓF_{y} or CHₓF_{y} plasma gas. x and y of CₓF_{y} and CHₓF_{y} may represent natural numbers. For example, CₓF_{y} may include C₄F₈ or C₄F₆, and CHₓF_{y} may include CH₂F₂. Subsequently, an operation S90 of removing the second mask pattern 53 may be performed. In other words, an operation S90 of removing the remaining portion of the second mask layer 52 may be performed.

When the second laser grooving process LG2 described with reference to FIG. 5F is performed, burrs may occur. The burrs may be generated from the first electric line 222, the first circuit insulating layer 221, the second connection pad 223b, the first bonding insulating layer 231, the first bonding pad 232, or/and the second mask layer 52. The burr may be understood as a defect that protrudes or forms a stepped portion near a cut surface due to the ductility of metal, etc. If the burrs are generated on the surface of the first bonding layer 230, the electrical characteristics and reliability of the front surface of the semiconductor chips 200a and 200b may be deteriorated.

According to one or more embodiments, the operation S70 of removing the first bonding layer 230 and the first circuit layer 220 from the inspection region TEG of the scribe lane region SL by performing the second laser grooving process LG2 may be performed in a state in which the second mask layer 52 covers the sidewall 221t of the remaining insulating layer 221r. Accordingly, the burrs that are generated in the inspection region TEG during the second laser grooving process LG2 may occur only on the surface of the second mask layer 52. Also, since the second mask layer 52 may be removed, the burrs may not be generated in the first circuit layer 220 and the first bonding layer 230. Accordingly, the electrical characteristics and reliability of the front surfaces of the semiconductor chips 200a and 200b may be improved. In particular, during the process of bonding the first structure 1 to the second structure 2 as shown in FIG. 2, substantially flat bonding surfaces may be provided to improve bonding characteristics.

FIG. 6 is a cross-sectional view illustrating the semiconductor chip 200 manufactured by the semiconductor chip manufacturing method according to one or more example embodiments. In particular, FIG. 6 illustrates one semiconductor chip 200 among the plurality of semiconductor chips 200a and 200b of the semiconductor wafer WF-7 in the seventh state in FIG. 5G.

Referring to FIG. 6, the semiconductor chip 200 may include a first semiconductor substrate 210, a first bonding layer 230 above the first semiconductor substrate 210, and a first circuit layer 220 between the first semiconductor substrate 210 and the first bonding layer 230. The semiconductor chip 200 may include a chip region CH and trench regions TR.

The first semiconductor substrate 210 may include semiconductor elements, such as silicon and germanium, or compound semiconductors, such as silicon carbide (SiC), gallium arsenide (GaAs), indium arsenide (InAs), and indium phosphide (InP), and may optionally include a TSV.

A device layer may be formed on the first semiconductor substrate 210, and the device layer may include transistors constituting an integrated circuit. The transistors constituting the integrated circuit may include, but not limited to, a MOSFET having a planar shape, a FinFET having an active region of a fin structure, a MBCFET™ including a plurality of channels stacked vertically on an active region, a GAAFET, a VFET, etc.

The integrated circuit may include volatile memory devices, such as a DRAM and a SRAM, and non-volatile memory devices, such as a PRAM, a magnetic MRAM, and a ReRAM.

The first circuit layer 220 may be disposed on the first semiconductor substrate 210. The first circuit layer 220 may include a first circuit insulating layer 221, a first electric line 222, and a first connection pad 223a. The first electric line 222 and the first connection pad 223a may be arranged within the first circuit insulating layer 221.

The first electric line 222 may be electrically connected to the integrated circuit of the device layer. The first connection pad 223a may be located in the chip region CH. A plurality of first connection pads 223a may be provided. The first connection pad 223a may be electrically connected to the corresponding first electric line 222.

The first electric line 222 and the first connection pad 223a may be arranged in the chip region CH. The first circuit insulating layer 221 may be located in the chip region CH and extend from the chip region CH to a portion of the trench region TR.

The first bonding layer 230 may be disposed on the first circuit layer 220. The first bonding layer 230 may include a first bonding insulating layer 231 and a first bonding pad 232 within the first bonding insulating layer 231. The first bonding layer 230 may correspond to the first bonding structure BS1 and/or the second bonding structure BS2 in FIG. 2. The first bonding insulating layer 231 may correspond to the first bonding insulating layer BI1 and/or the second bonding insulating layer BI2 in FIG. 2. The first bonding pad 232 may correspond to the first bonding pad BP1 and/or the second bonding pad BP2 in FIG. 2.

A plurality of first bonding pads 232 may be provided. The first bonding pad 232 may be located in the chip region CH. The first bonding pad 232 may be connected to the first connection pad 223a. The first bonding pad 232 may be electrically connected to the first electric line 222 via the first connection pad 223a. The first bonding pad 232 may be electrically connected to the integrated circuit of the first semiconductor substrate 210 via the first connection pad 223a and the first electric line 222.

The first bonding insulating layer 231 may be located in the chip region CH and extend from the chip region CH to a portion of the trench region TR. The first bonding insulating layer 231 may cover an upper surface 210a of the first semiconductor substrate 210 only in a portion of the trench region TR. Accordingly, an upper edge surface 210e of the first semiconductor substrate 210 may not be covered by the first bonding insulating layer 231 (i.e., the upper edge surface 210e may be exposed). The upper edge surface 210e of the first semiconductor substrate 210 may not be covered by the first bonding layer 230.

Both a portion of the first circuit insulating layer 221 and a portion of the first bonding insulating layer 231, which are arranged in the trench region TR, may be referred to as a remaining insulating layer 221r. The upper edge surface 210e of the first semiconductor substrate 210 may not be covered by the remaining insulating layer 221r. The upper edge surface 210e of the first semiconductor substrate 210 may not be covered by the first circuit layer 220.

For example, the first bonding insulating layer 231 may include silicon oxide, silicon nitride, silicon oxynitride, silicon carbide, silicon oxycarbide, silicon carbonitride, or a combination thereof. The first bonding pad 232 may include any one of copper (Cu), nickel (Ni), gold (Au), and silver (Ag), or an alloy thereof.

The horizontal width of the first semiconductor substrate 210 may be a third width W3. The horizontal width of the first circuit layer 220 may be a fourth width W4. The horizontal width of the first bonding layer 230 may also be the fourth width W4. The third width W3 of the first semiconductor substrate 210 may be greater than the fourth width W4 of the first circuit layer 220 or first bonding layer 230. That is, the fourth width W4 may be less than the third width W3. Since the fourth width W4 is less than the third width W3, the upper edge surface 210e of the first semiconductor substrate 210 may be exposed. That is, the first circuit layer 220 may not cover the upper edge surface 210e. The upper edge surface 210e may not be covered by the first circuit layer 220.

The angle formed between a sidewall 221t of the remaining insulating layer 221r and the upper surface 210a of the first semiconductor substrate 210 may be a first angle θ1 as shown in FIG. 5D or 5G. The first angle θ1 may be about 90 degrees or may be at least about 60 degrees but less than about 90 degrees. The angle formed between the upper edge surface 210e of the first semiconductor substrate 210 and a sidewall 210t of the first semiconductor substrate 210 may be a second angle θ2 as shown in FIG. 5G. The second angle θ2 may be about 90 degrees or may be greater than about 90 degrees but less than about 120 degrees.

The sidewall 221t of the remaining insulating layer 221r may be spaced apart from the sidewall 210t of the first semiconductor substrate 210. The sidewall 221t of the remaining insulating layer 221r, the upper edge surface 210e of the first semiconductor substrate 210, and the sidewall 210t of the first semiconductor substrate 210 may form a stepped structure.

FIG. 7 is a diagram illustrating a die-to-wafer bonding process according to one or more example embodiments. That is, FIG. 7 shows a process of bonding semiconductor chips manufactured with reference to FIGS. 5A to 6 on a wafer.

Referring to FIG. 7, semiconductor chips 20′ may be pre-bonded, by using a pick-and-place device 40, to a wafer structure 10W, on which a plurality of semiconductor structures 10 are formed, on an electrostatic chuck 30. The wafer structure 10W may include the semiconductor structures 10 which are separated from each other by scribe lanes SL′. Each of the semiconductor structures 10 may include a first substrate structure 10S and a first bonding structure BS1 on the first substrate structure 10S.

Each of the semiconductor chips 20′ may correspond to the semiconductor chip 200 of FIG. 6. The semiconductor chips 20′ may include bonding pads (e.g., 232 in FIG. 6) and may be arranged directly on the semiconductor structures 10. Here, “pre-bonding” may represent placing the semiconductor chip 20′ on the corresponding semiconductor structure 10 without applying pressure or heat. Subsequently, the semiconductor chip 20′ and the semiconductor structure 10 may be coupled to each other by performing dielectric-to-dielectric bonding and copper-to-copper bonding.

As shown in the enlarged cross-sectional view of FIG. 7, the semiconductor chip 20′ may include a second bonding structure BS2 having a width less than the width of a second substrate structure 11S.

FIG. 8 is a cross-sectional view illustrating a semiconductor chip 200 and a semiconductor package 1000 according to one or more example embodiments.

Referring to FIG. 8, the semiconductor package 1000 according to one or more embodiments may include a semiconductor structure 100 and the semiconductor chip 200 stacked on the semiconductor structure 100 in the vertical direction. The semiconductor structure 100 and the semiconductor chip 200 may have a structure (e.g., referred to as hybrid bonding, direct bonding, etc.) in which elements exposed on the upper surface of the semiconductor structure 100 and the lower surface of the semiconductor chip 200 are directly bonded to each other without separate connection members (e.g. metal pillars, solder bumps, etc.).

For example, dielectric-to-dielectric bonding and copper-to-copper bonding may be formed on the interface between the semiconductor structure 100 and the semiconductor chip 200. A second bonding layer 120 of the semiconductor structure 100 and a first bonding layer 230 of the semiconductor chip 200 may be bonded to each other. The first bonding layer 230 of the semiconductor chip 200 may correspond to the first bonding layer 230 in FIGS. 5A to 6.

As a semiconductor wafer-based structure, the semiconductor structure 100 may include a second semiconductor substrate 110, a second bonding layer 120, a second circuit layer 130, a through-via 140, and a front cover layer 150. For example, the semiconductor structure 100 may include a silicon interposer substrate, a semiconductor die, etc. When the semiconductor structure 100 includes a semiconductor die, the semiconductor structure 100 and the semiconductor chip 200 stacked thereon may include chiplets that constitute a multi-chip module (MCM), but the embodiment is not limited thereto.

The second semiconductor substrate 110 may include semiconductor elements, such as silicon and germanium, or compound semiconductors, such as silicon carbide (SiC), gallium arsenide (GaAs), indium arsenide (InAs), and indium phosphide (InP). The second semiconductor substrate 110, which is a portion of a semiconductor wafer, may be separated into a plurality of second semiconductor substrates 110 by cutting the semiconductor wafer.

The second bonding layer 120 may be disposed on a rear surface 110BS of the second semiconductor substrate 110 and include a second bonding insulating layer 121 and a second bonding pad 122. The second bonding insulating layer 121 may include an insulating material that may be coupled to a first bonding insulating layer 231 of the semiconductor chip 200. For example, the second bonding insulating layer 121 may include at least one of silicon oxide, silicon nitride, silicon oxynitride, silicon carbide, silicon oxycarbide, and silicon carbonitride.

Similarly, the second bonding pad 122 may include a conductive material that may be coupled to a first bonding pad 232 of the semiconductor chip 200. For example, the second bonding pad 122 may include any one of copper (Cu), nickel (Ni), gold (Au), and silver (Ag), or an alloy thereof.

A dielectric film (e.g., an oxide nitride oxide (ONO) layer) may cover the rear surface 110BS of the second semiconductor substrate 110. The dielectric film may electrically insulate the second bonding pad 122 from a semiconductor material that constitutes the second semiconductor substrate 110.

The second circuit layer 130 may be disposed on a front surface 110FS of the second semiconductor substrate 110 and may include a second circuit insulating layer 131 and a second electric line 132. The second circuit insulating layer 131 may include at least one of silicon oxide, silicon nitride, and silicon oxynitride.

The second electric line 132 may redistribute the second bonding pad 122 or the through-via 140 disposed on the rear surface 110BS of the second semiconductor substrate 110 and may be formed as a multi-layer structure that includes a plurality of wiring lines and a plurality of wiring vias. Each of the wiring line and the wiring via may include, for example, aluminum (Al), gold (Au), cobalt (Co), copper (Cu), nickel (Ni), lead (Pb), tantalum (Ta), tellurium (Te), titanium (Ti), tungsten (W), or a metal material containing a combination thereof. A barrier film containing titanium (Ti), titanium nitride (TiN), tantalum (Ta), or tantalum nitride (TaN) may be provided between the wiring line and/or wiring via and the second circuit insulating layer 131.

According to one or more embodiments, the second circuit layer 130 may include individual devices arranged on the front surface 110FS of the second semiconductor substrate 110 and constituting an integrated circuit. In this case, the second electric line 132 may be electrically connected to the individual devices. The individual devices may include FETs, such as a planar FET and a FinFET, memory devices, such as flash memory, DRAM, SRAM, electrically erasable programmable read-only memory (EEPROM), PRAM, MRAM, Ferroelectric random access memory (FeRAM), and resistive RAM (RRAM), logic devices, such as AND, OR, and NOT gates, and other active and/or passive devices, such as system large scale integration (LSI), CMOS image sensor (CIS), and micro electro mechanical system (MEMS).

The front cover layer 150 may be disposed below the second circuit layer 130. The front cover layer 150 may include a front insulating layer 151 and a front pad 152. The front pad 152 may be electrically connected to the second bonding pad 122 via the second electric line 132 and the through-via 140.

The front insulating layer 151 may include at least one of silicon oxide, silicon nitride, silicon oxynitride, silicon carbide, silicon oxycarbide, and silicon carbonitride.

The front pad 152 may include a metal material similar to that of the second electric line 132, but may not necessarily include the same type of metal material as the second electric line 132. The front pad 152 may include any one of copper (Cu), nickel (Ni), gold (Au), and silver (Ag), or an alloy thereof.

The front pad 152 may provide a connection terminal through which the semiconductor structure 100 and the semiconductor chip 200 may be electrically connected to an external device. A separate connection member 159 (e.g., a solder ball, a copper pillar, etc.) may be disposed below the front pad 152, but the embodiments are not limited thereto. The semiconductor structure 100 may be hybrid-bonded to another structure (e.g., a silicon interposer) without a connection member such as a solder ball.

The through-via 140 may pass through the second semiconductor substrate 110 and be electrically connected to the second electric line 132. The through-via 140 may extend partially to the inside of the second bonding insulating layer 121 and the inside of the second circuit insulating layer 131 of the second circuit layer 130.

According to one or more embodiments, the through-via 140 may be electrically connected, via the second electric line 132 of the second circuit layer 130, to the individual devices arranged on the front surface 110FS of the second semiconductor substrate 110.

The through-via 140 may include a through-electrode and a barrier film surrounding a side surface of the through-electrode. The through-electrode may include, for example, tungsten (W), titanium (Ti), aluminum (Al), or copper (Cu). The barrier film may include metal compounds, such as tungsten nitride (WN), titanium nitride (TiN), and tantalum nitride (TaN).

A via insulating film may be formed on the side surface of the through-via 140. The via insulating film may include a single layer film or a multilayer film. The via insulating film may include silicon oxide, silicon oxynitride, silicon nitride, polymer, or a combination thereof.

The semiconductor chip 200 may be disposed on the semiconductor structure 100. The semiconductor chip 200 may include a first semiconductor substrate 210, a first circuit layer 220, and a first bonding layer 230. FIG. 8 illustrates only one semiconductor chip 200, but the number of semiconductor chips 200 according to embodiments is not limited thereto. For example, at least two semiconductor chips may be stacked vertically or arranged horizontally on the semiconductor structure 100.

The semiconductor chip 200 of FIG. 8 may correspond to a state when the semiconductor chip 200 of FIG. 6 is turned over.

A lower edge surface 210le of the first semiconductor substrate 210 of FIG. 8 (e.g., an edge portion of the lower surface of the first semiconductor substrate 210) may correspond to the upper edge surface 210e of the first semiconductor substrate 210 of FIG. 6. The angle formed between a sidewall 210t of the first semiconductor substrate 210 and the lower edge surface 210le of the first semiconductor substrate 210 (same as the upper edge surface 210e in FIG. 6) may be the same as the second angle θ2 of FIG. 5G. The sidewall 221t of the first circuit layer 220, the lower edge surface 210le of the first semiconductor substrate 210, and the sidewall 210t of the first semiconductor substrate 210 may form a stepped structure. The lower edge surface 210le may not be covered by the first circuit layer 220.

The semiconductor chip 200 of FIG. 8 may be similar features to the semiconductor chip 200 of FIG. 6, and thus, other repeated descriptions thereof may be omitted.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor chip comprising:
a semiconductor substrate;
a bonding layer above an upper surface of the semiconductor substrate, the bonding layer comprising a bonding pad and a bonding insulating layer surrounding at least a portion of a side surface of the bonding pad; and
a circuit layer between the semiconductor substrate and the bonding layer, the circuit layer comprising a circuit insulating layer and an electric line in the circuit insulating layer,
wherein a horizontal width of the circuit layer is less than a horizontal width of the semiconductor substrate, and
wherein a sidewall of the semiconductor substrate is spaced apart from a sidewall of the circuit layer in a horizontal direction.

2. The semiconductor chip of claim 1, wherein an upper edge surface of the semiconductor substrate is spaced apart from the circuit layer in the horizontal direction, and
wherein the upper edge surface of the semiconductor substrate is exposed.

3. The semiconductor chip of claim 2, wherein an angle formed between the sidewall of the semiconductor substrate and the upper edge surface of the semiconductor substrate is greater than about 90 degrees and less than about 120 degrees.

4. The semiconductor chip of claim 1, wherein the sidewall of the circuit layer, an upper edge surface of the semiconductor substrate, and the sidewall of the semiconductor substrate form a stepped structure.

5. The semiconductor chip of claim 1, wherein an angle formed between the upper surface of the semiconductor substrate and the sidewall of the circuit layer is at least about 60 degrees and less than about 90 degrees.

6. The semiconductor chip of claim 1, wherein the circuit layer further comprises a connection pad connected to the electric line, and
wherein the connection pad contacts the bonding pad.

7. The semiconductor chip of claim 6, wherein a horizontal width of the connection pad is greater than a horizontal width of the bonding pad.

8. A semiconductor package comprising:
a semiconductor structure; and
a semiconductor chip on the semiconductor structure,
wherein the semiconductor structure comprises:
a first semiconductor substrate;
a first bonding layer on an upper surface of the first semiconductor substrate, the first bonding layer comprising a first bonding pad and a first bonding insulating layer surrounding at least a portion of a side surface of the first bonding pad; and
a first circuit layer on a lower surface of the first semiconductor substrate, the first circuit layer comprising a first circuit insulating layer and a first electric line in the first circuit insulating layer,
wherein the semiconductor chip comprises:
a second semiconductor substrate;
a second bonding layer below the second semiconductor substrate, the second bonding layer comprising a second bonding pad and a second bonding insulating layer surrounding at least a portion of a side surface of the second bonding pad; and
a second circuit layer between the second semiconductor substrate and the second bonding layer, the second circuit layer comprising a second circuit insulating layer and a second electric line in the second circuit insulating layer, and
wherein a horizontal width of the second circuit layer is less than a horizontal width of the second semiconductor substrate.

9. The semiconductor package of claim 8, wherein the first bonding pad contacts the second bonding pad are in contact with each other, and
wherein the first bonding insulating layer contacts the second bonding insulating layer.

10. The semiconductor package of claim 8, wherein the semiconductor structure further comprises:
a front cover layer below the first circuit layer, the front cover layer comprising a front pad and a front insulating layer surrounding at least a portion of a side surface of the front pad; and
a connection member below the front pad and connected to the front pad.

11. The semiconductor package of claim 8, wherein a lower edge surface of the second semiconductor substrate is exposed.

12. The semiconductor package of claim 11, wherein an angle formed between a lower surface of the second semiconductor substrate and a sidewall of the second circuit layer is at least about 60 degrees and less than about 90 degrees.

13. The semiconductor package of claim 8, wherein a side surface of the second circuit layer, a lower edge surface of the second semiconductor substrate, and a sidewall of the second semiconductor substrate form a stepped structure.

14. A semiconductor chip manufacturing method comprising:
preparing a semiconductor wafer comprising a plurality of chip regions and a plurality of scribe lane regions between the plurality of chip regions, wherein the semiconductor wafer comprises a semiconductor substrate, a bonding layer above the semiconductor substrate, and a circuit layer between the semiconductor substrate and the bonding layer, and wherein each of the plurality of scribe lane regions comprises an inspection region and trench regions on both sides of the inspection region;
forming a first mask layer on a front surface of the semiconductor wafer;
forming a first mask pattern by performing a first laser grooving process on the first mask layer in the trench regions;
removing a portion of a bonding insulating layer of the bonding layer and removing a portion of a circuit insulating layer of the circuit layer by performing a first plasma process in the trench regions using the first mask pattern as an etch mask;
removing the first mask pattern;
forming a second mask layer filling a space corresponding to the removed portion of the bonding insulating layer and the removed portion of the circuit insulating layer;
removing at least a portion the second mask layer, the bonding layer, and the circuit layer from the inspection region by performing a second laser grooving process;
removing the semiconductor substrate from the inspection region by performing a second plasma process; and
removing the second mask layer from at least one region other than the inspection region.

15. The semiconductor chip manufacturing method of claim 14, wherein the second laser grooving process is performed in a state in which the second mask layer is covering a sidewall of the circuit layer in a portion of at least one trench region that is adjacent to at least one chip region of the plurality of chip regions.

16. The semiconductor chip manufacturing method of claim 14, wherein, in at least one trench region and prior to the second laser grooving process, the second mask layer comprises a first portion that is adjacent to the inspection region and a second portion that is adjacent to a chip region,
wherein, during the second laser grooving process, the first portion of the second mask layer is removed, and
wherein, after the second laser grooving process, the second portion of the second mask layer remains.

17. The semiconductor chip manufacturing method of claim 14, wherein the circuit layer further comprises an electric line in the circuit insulating layer,
wherein the bonding layer further comprises a bonding pad in the bonding insulating layer, and
wherein the electric line and the bonding pad are spaced apart from the trench regions in a horizontal direction.

18. The semiconductor chip manufacturing method of claim 17, wherein the performing of the first laser grooving process comprises forming a first opening while removing a portion of the first mask layer, and
wherein a horizontal width of the first opening is less than a horizontal width of at least one trench region.

19. The semiconductor chip manufacturing method of claim 14, wherein, after the second plasma process, a horizontal width of the circuit layer is less than a horizontal width of the semiconductor substrate.

20. The semiconductor chip manufacturing method of claim 14, wherein the circuit layer further comprises an electric line in the circuit insulating layer and a connection pad in an upper portion of the circuit layer and connected to the electric line, and
wherein the inspection region comprises an align-key or an inspection circuit, the align-key or the inspection circuit comprising the electric line and the connection pad.
